(19) United States
(12) Patent Application Publication
(10) Pub. No.: US 2025/0036842 A1
(43) Pub. Date: Jan. 30, 2025

(54) DATAFLOW GASKETS WITH CIRCULAR BUFFERS

(71) Applicant: Analog Devices, Inc., Wilmington, MA (US)

(72) Inventors: Christopher Mayer, Dover, MA (US); Sudhir Desai, Mansfield, MA (US); Arash Azizimazreah, Merrimack, NH (US)

(21) Appl. No.: 18/781,029

(22) Filed: Jul. 23, 2024

Related U.S. Application Data
(60) Provisional application No. 63/515,421, filed on Jul. 25, 2023.

(51) Int. Cl. G06F 30/347; G06F 13/40; H04L 49/101

(52) U.S. Cl. CPC G06F 30/347; G06F 13/4022; H04L 49/101

(57) ABSTRACT

Apparatus and methods for facilitating data movement among circuit blocks are disclosed. In certain embodiments, dataflow gaskets with circular buffers are deployed in any number or arrangement to achieve efficient on-chip data movement among different circuit blocks of the die. Each dataflow gasket can be attached to a corresponding circuit block using tightly coupled memories to provide low latency and fast access to incoming and outgoing data streams. Furthermore, memory allocation and buffer management can be handled by the internal logic in the dataflow gasket to reduce or eliminate software development efforts. For example, the dataflow gasket can use circular buffers to allow the circuit block to access the dataflow gasket's memories without needing to understand the internal memory addressing of the dataflow gasket.

### CROSS-REFERENCE TO RELATED APPLICATIONS

The present application claims priority to U.S. Provisional Patent Application No. 63/515,421, filed Jul. 25, 2023, and titled “DATAFLOW GASKETS WITH CIRCULAR BUFFERS,” the entirety of which is hereby incorporated herein by reference.

### FIELD OF THE DISCLOSURE

Embodiments of the invention relate to electronic systems, and more particularly to, dataflow gaskets for facilitating data movement among circuit blocks.

### BACKGROUND

Various techniques can be used to move data between electronic circuits. For example, certain electronic systems use standard bussing for interconnecting circuit blocks for data movement. However, data traffic can be of many types (memory, peripheral, and/or computation) having varying characteristics. Thus, when standard bussing is designed for overall throughput, the bussing can stall at times while slower systems (i.e. off-chip memory) absorb high traffic periods.

In another example, point-to-point bussing can be used to connect each compute block to every other compute block. Point-to-point bussing can support any arbitrary data traffic between circuit blocks but can have unnecessary area and/or power overhead.

### SUMMARY OF THE DISCLOSURE

Apparatus and methods for facilitating data movement among circuit blocks are disclosed. In certain embodiments, dataflow gaskets with circular buffers are deployed in any number or arrangement to achieve efficient on-chip data movement among different circuit blocks of the die. Each dataflow gasket can be attached to a corresponding circuit block using tightly coupled memories to provide low latency and fast access to incoming and outgoing data streams. Furthermore, memory allocation and buffer management can be handled by the internal logic in the dataflow gasket to reduce or eliminate software development efforts. For example, the dataflow gasket can use circular buffers to allow the circuit block to access the dataflow gasket's memories without needing to understand the internal memory addressing of the dataflow gasket.

In one aspect, an integrated circuit (IC) can include a first circuit block and a first dataflow gasket coupled to the first circuit block. The first dataflow gasket can include a crossbar switch electrically connected to interconnect of a network of dataflow gaskets, and a memory circuit electrically connected to the crossbar switch and accessible to the first circuit block and the first dataflow gasket. The memory can include at least one circular buffer.

In another aspect, a method of dataflow in an IC can include receiving first data from interconnect of a network of dataflow gaskets as an input to a crossbar switch of a first dataflow gasket and writing the first data to a memory circuit of the first dataflow gasket. The memory circuit can be coupled to the crossbar switch. The method can further include providing the first data from the memory circuit to a first circuit block that is coupled to the first dataflow gasket. Providing the first data to the first circuit can include using a first circular buffer to read the first data from the memory circuit.

In another aspect, a dataflow gasket can include local device interconnect for coupling to a circuit block, a crossbar switch electrically connected to interconnect of a network of dataflow gaskets, and a memory circuit electrically connected to the crossbar switch and accessible to the first circuit block and the first dataflow gasket. The memory can include at least one circular buffer.

### BRIEF DESCRIPTION OF THE DRAWINGS

FIG. 1 is a schematic diagram of one embodiment of a dataflow gasket.

FIG. 2A is a schematic diagram of one embodiment of an integrated circuit (IC) including circuit blocks interconnected by dataflow gaskets.

FIG. 2B is a schematic diagram of another embodiment of an IC including circuit blocks interconnected by dataflow gaskets.

FIG. 3 is a schematic diagram of another embodiment a dataflow gasket.

FIG. 4 is a schematic diagram of one embodiment of data stream merging using dataflow gaskets.

FIG. 5 is a schematic diagram of one embodiment of data stream forking using dataflow gaskets.

FIG. 6A is a schematic diagram of one embodiment of memory addressing for a dataflow gasket.

FIG. 6B is a schematic diagram of another embodiment of memory addressing for a dataflow gasket.

FIG. 7 is a schematic diagram of another embodiment of a dataflow gasket.

FIG. 8 is a schematic diagram of one embodiment of an address space for merging data using a circular buffer of a dataflow gasket.

FIG. 9A is a schematic diagram of one example of memory allocation in a circular buffer.

FIG. 9B is a schematic diagram of another example of memory allocation in a circular buffer.

### DETAILED DESCRIPTION

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As integrated circuit (IC) technology is scaled to smaller technology nodes, the transistor density (or number of transistors that can be integrated into a unit area of an IC) increases drastically. The increased density translates to heterogeneous complex chips in which multiple blocks with different architectures are combined into a single die to provide a System-on-Chip (SoC). For example, a single die can include a combination of central processing units (CPUs), digital signal processors (DSPs), and neural processing units (NPUs). An NPU is also referred to herein as a neural network engine (NNE).

On the other hand, in the past few years, neural networks such as convolution neural networks (CNNs), recurrent neural networks (RNNs), and multi-layer perception networks (MLPs) have been shown to outperform traditional DSP algorithms in many fields such as computer vision and speech recognition.

Accordingly, many current and future IC applications consist of DSP algorithms and neural network models. In these applications, while fast data converters (for example, high-speed analog-to-digital converters or ADCs) provide the data for processing, different parts of computational graphs are mapped onto different circuit blocks such as CPUs, DSPs and NPUs. Such mapping gives rise to significant data movement among different circuit blocks. Thus, data transfer between circuit blocks is key to achieving fast and efficient processing for these signal processing applications.

Certain ICs use standard bussing to build a network-on-chip (NoC) for interconnecting circuit blocks for data movement. However, a standard NoC has many types of traffic (memory, peripheral, and/or computation) having varying characteristics. Standard bussing is typically designed for overall throughput, and thus can stall at times while slower systems (i.e. off-chip memory) absorb high traffic periods.

In another example, point-to-point bussing can be used to connect each compute block to every other compute block. Point-to-point bussing can support any arbitrary data traffic between circuit blocks. However, in many domain-specific applications such as signal processing, only a handful of traffic patterns are generated during run time. Accordingly, such generality is not needed, but rather causes an inefficient usage of resources (transistors and wires) and leads to unnecessary area and/or power overhead. For example, point-to-point bussing is not scalable and requires exponentially more wires as the number of compute blocks increases.

### Overview of Example Embodiments of Dataflow Gaskets

The following section provides an overview of example embodiments for dataflow gaskets. While certain embodiments have been described, these embodiments have been presented by way of example only and are not intended to limit the scope of the disclosure. Any suitable combination of features of the embodiments described can be combined to provide further embodiments.

Apparatus and methods for facilitating data movement among circuit blocks are disclosed. In certain embodiments, dataflow gaskets with circular buffers are provided. Such dataflow gaskets can be deployed in any number or arrangement to achieve efficient on-chip data movement among different circuit blocks of the die. Each dataflow gasket can be attached to a corresponding circuit block using tightly coupled memories to provide low latency and fast access to incoming and outgoing data streams. Furthermore, memory allocation and buffer management can be handled by the internal logic in the dataflow gasket to reduce or eliminate software development efforts. For example, the dataflow gasket can use circular buffers to allow the circuit block to access the dataflow gasket's memories without needing to understand the internal memory addressing of the dataflow gasket.

The dataflow gaskets can have networking capabilities in which dataflow gaskets can be connected using fast internal interconnects. The internal interconnect topology can be customizable based on the traffic patterns that exist in the computational graph of a particular signal processing application. Accordingly, an efficient usage of resources used for interconnects is provided.

Furthermore, the dataflow gaskets can be integrated into an IC alongside of traditional NoCs in different configurations. Thus, the IC can include a network of dataflow gaskets alongside other levels of bussing providing varying performance levels, such as different degrees of connectivity, throughput and/or latency.

### Description of Embodiments of Dataflow Gaskets Shown in Figures

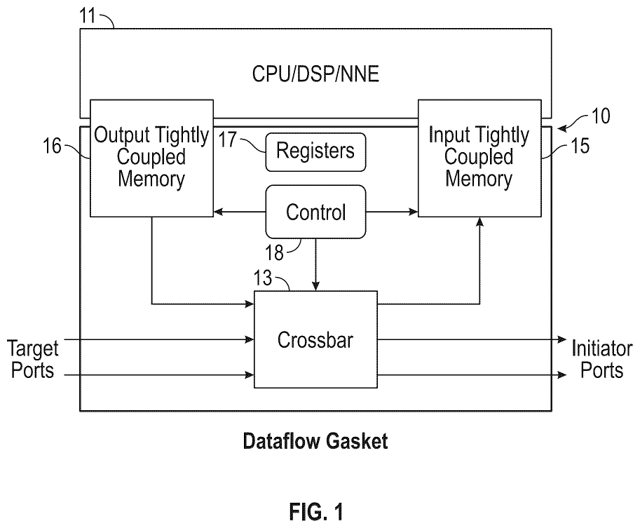

FIG. 1 is a schematic diagram of one embodiment of a dataflow gasket 10. The dataflow gasket 10 is depicted as being coupled to a circuit block 11, which can be, for example, a CPU, DSP, NNE, reconfigurable compute unit (for example, a field programmable gate array or FPGA), or other intellectual property (IP) circuit block. The dataflow gasket 10 includes a crossbar switch 13, an input memory 15, an output memory 16, registers 17, and a control circuit 18. The dataflow gasket 10 can be interconnected with other dataflow gasket(s) on-chip as part of a larger NoC. Thus, dataflow gaskets can be arranged on an IC to form a desired NoC suitable for a particular IC design or application. An IC is also referred to herein as a semiconductor die or chip.

In the illustrated embodiment, the crossbar switch 13 includes an input-side that is coupled to input ports (also referred to herein as target ports) and to the output memory 16. The input ports receive data packets from a network of dataflow gaskets. The crossbar switch 13 also includes an output-side that is coupled to output ports (also referred to herein as initiator ports) and to the input memory 15. The output ports provide data packets to other dataflow gasket(s) in the network. The crossbar switch 13 is controlled by the control circuit 18 to provide desired switch connectivity between the input side and the output side.

Accordingly, the crossbar switch 13 can provide desired connections between the input side and the output side to thereby route data into and out of the dataflow gasket 10. In a first example, data received on the input ports is routed by the crossbar switch 13 to the input memory 15. In a second example, data received on the input ports is routed by the crossbar switch 13 to the output ports. In a third example, data from the output memory 16 is routed by the crossbar switch 13 to the output ports.

With continuing reference to FIG. 1, the registers 17 (also referred to herein as a register file) are used to hold a variety of information, including, for example, gasket identification information for identifying the gasket within the network of dataflow gaskets, a routing table, input stream configuration for input stream(s), output stream configuration for output stream(s), and/or feature configuration data for controlling a variety of gasket features.

The input memory 15 receives data from the crossbar switch 13, and is tightly coupled to the circuit block 11. Additionally, the output memory 16 provides data to the crossbar switch 13 and is tightly coupled to the circuit block 11. Both the circuit block 11 and the dataflow gasket 10 have access to the input memory 15 and the output memory 16. In one example, the dataflow gasket 10 can write to the input memory 15 and read from the output memory 16, while the circuit block 11 can read from the input memory 15 and write to the output memory 16. However, other implementations are possible, such as configurations in which both the dataflow gasket 10 and the circuit block 11 can read and write to both the input memory 15 and the output memory 16.

In accordance with the teachings herein, at least one of the input memory 15 or the output memory 16 is implemented with a circular buffer to facilitate memory allocation and dataflow. By using circular buffer(s), complexity in reading and writing over the memory interface between the circuit block 11 and the dataflow gasket 10 is reduced. Accordingly, during design of an IC, a desired architecture of circuit blocks (CPUs, DSPs, NNEs, reconfigurable compute units, and/or other IP blocks) can be placed and easily interconnected to one another by a network of dataflow gaskets with little to no design overhead.

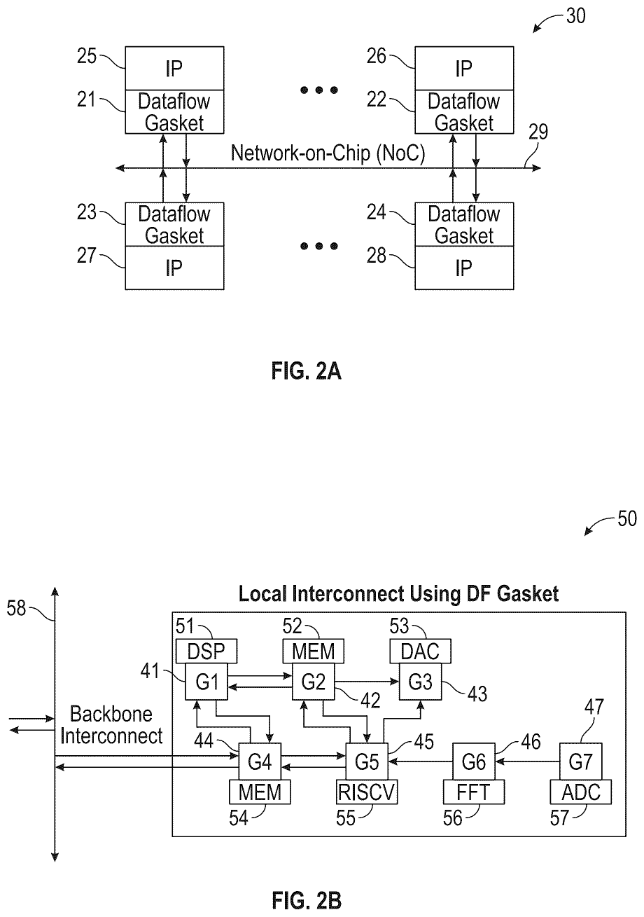

FIG. 2A is a schematic diagram of one embodiment of an IC 30 including circuit blocks interconnected by dataflow gaskets.

In the illustrated embodiment, the IC 30 includes a first dataflow gasket 21, a second dataflow gasket 22, a third dataflow gasket 23, a fourth dataflow gasket 24, a first circuit block 25, a second circuit block 26, a third circuit block 27, a fourth circuit block 28, and interconnect forming an NoC 29. Although four dataflow gaskets and four circuit blocks are depicted, more or fewer gaskets and circuit blocks can be included as indicated by the ellipsis.

As shown in FIG. 2A, the NoC 29 interconnects the dataflow gaskets 21-24 to one another. Additionally, the dataflow gaskets 21-24 are connected to the circuit blocks 25-28, respectively. The dataflow gaskets 21-24 and NoC 29 allow the efficient transfer of data between the depicted circuit blocks 25-28.

Although one arrangement of dataflow gaskets is shown, dataflow gaskets can be connected in a wide variety of ways. Indeed, dataflow gaskets serve as building blocks for dataflow that allow for implementing the NoC 29 to achieve standard topologies (for instance, mesh or ring) as well as any custom topology.

FIG. 2B is a schematic diagram of another embodiment of an IC 50 including circuit blocks interconnected by dataflow gaskets.

In the illustrated embodiment, the IC 50 includes dataflow gaskets 41 (G1), 42 (G2), 43 (G3), 44 (G4), 45 (G5), 46 (G6), and 47 (G7). The dataflow gaskets 41-47 are interconnected with one another using an example custom interconnect topology. As shown in FIG. 2B by the directional arrows, a particular gasket can communicate with a subset of the other gasket(s). Such communication can be unidirectional (read or write only) or bidirectional (read and write).

The gaskets 41-47 are each connected to a particular circuit block, which are of varying types of IP blocks, in this embodiment. In particular, the IC 50 includes a DSP 51 coupled to the dataflow gasket 41, a memory 52 coupled to the dataflow gasket 42, a digital-to-analog converter (DAC) 53 coupled to the dataflow gasket 43, a memory 54 coupled to the dataflow gasket 44, a fifth generation reduced instruction set computer (RISCV or RISC-V) 55 coupled to the dataflow gasket 45, a fast Fourier transform (FFT) processor 56 coupled to the dataflow gasket 46, and an ADC 57 coupled to the dataflow gasket 47.

The IC 50 depicts one example application that can benefit from the use of dataflow gaskets to provide efficient transform of data between various circuit blocks. Although one example topology is shown, dataflow gaskets can be deployed in a wide variety of standard, semi-custom, or custom topologies to facilitate dataflow between any desired circuit blocks. Such dataflow can be further expanded by connection of one or more of the dataflow gaskets to backbone interconnect 58, thereby allowing connectivity to further components.

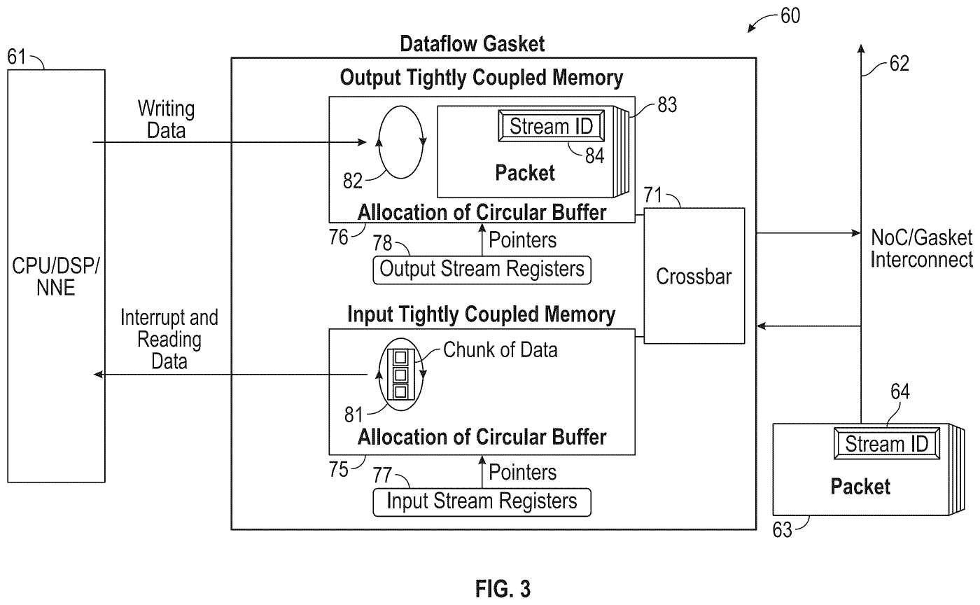

FIG. 3 is a schematic diagram of another embodiment a dataflow gasket 60. The dataflow gasket 60 is depicted as being coupled to a circuit block 61, which can be, for example, a CPU, DSP, NNE, reconfigurable compute unit, or other IP circuit block such as any of those shown above with reference to FIG. 2B. The dataflow gasket 60 includes a crossbar switch 71, an input memory 75, an output memory 76, input stream registers 77, and output stream registers 78. Although not shown in FIG. 3, the dataflow gasket 60 can include additional functional and control circuitry, which has not been depicted in FIG. 3 for clarity of the figure.

As shown in FIG. 3, the crossbar switch 71 is connected to gasket interconnect 62 that is interconnected with other dataflow gasket(s) as part of an NoC. As shown in FIG. 3, the gasket interconnect 62 is used to send and receive data packets, such as the data packet 63, which has a stream identification (ID) 64.

With continuing reference to FIG. 3, the input memory 75 is tightly coupled to the circuit block 61. Such tight coupling can be achieved in any suitable manner, including, but not limited to, using a custom or non-custom memory interface with a fixed latency read path.

In one example, a two-cycle pipelined bus performs a read operation by broadcasting a read transaction request on a first cycle, and returning data on a second cycle, in which the second cycle can contain another transaction request. The latency is substantially fixed between the read request and the delivery of the data. For instance, an Advanced High-performance Bus (AHB) can operate in this manner to provide tight coupling and enable one transfer per cycle.

As shown in FIG. 3, data received from the gasket interconnect 62 can be provided from the crossbar switch 71 for writing to the input memory 75. Such writing can be facilitated by the use of the input stream registers 77. The input memory 75 includes a circular buffer 81, which is used by the circuit block 61 for reading data from the input memory 75. The circular buffer 81 simplifies memory addressing for the circuit block 61, thereby providing a memory interface between the circuit block 61 and the dataflow gasket 60 that avoids a need for the circuit block 61 to understand the internal memory addressing of the input memory 75. As shown in FIG. 3, the circular buffer 81 also selectively activates an interrupt signal to alert the circuit block 61 as to when new data is available for reading.

In the illustrated embodiment, the output memory 76 is tightly coupled to the circuit block 61, which can write data to the output memory 76. Additionally, the output memory 76 can provide data in the form of data packets (for example, data packet 83 with stream ID 84) to the gasket interconnect 62 by way of the crossbar switch 71. The output of data from the output memory 76 can be facilitated by the use of the output stream registers 78. The output memory 76 includes a circular buffer 82, which is used by the circuit block 62 for writing data to the output memory 76. The circular buffer 82 simplifies memory addressing for the circuit block 61, thereby providing a memory interface between the circuit block 61 and the dataflow gasket 60 that avoids a need for the circuit block 61 to understand the internal memory addressing of the output memory 76.

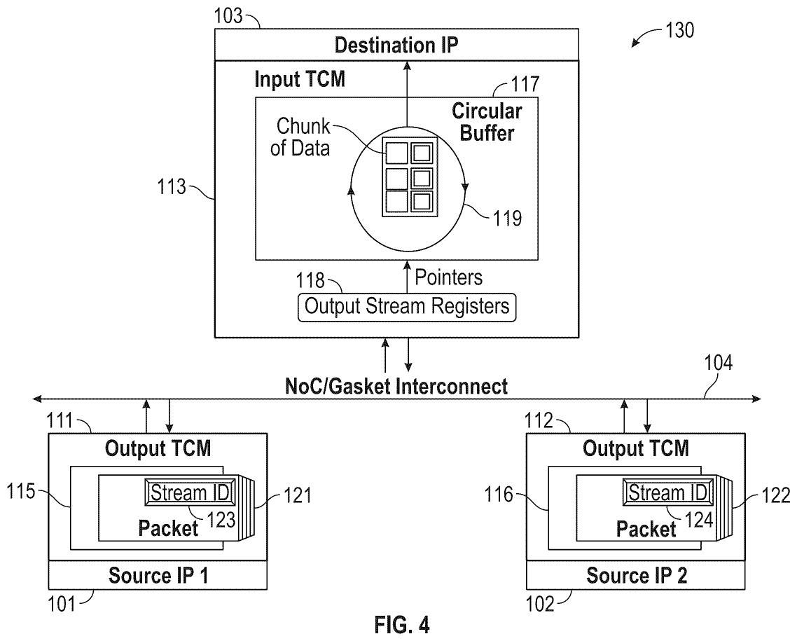

FIG. 4 is a schematic diagram of one embodiment of data stream merging 130 using dataflow gaskets. As shown in FIG. 4, a first source IP circuit block 101 is connected to a first dataflow gasket 111, a second source IP circuit block 102 is connected to a second dataflow gasket 112, and a destination IP circuit block 103 is connected to a third dataflow gasket 113. Additionally, the first dataflow gasket 111, the second dataflow gasket 112, and the third dataflow gasket 113 are connected to one another by gasket interconnect or NoC 104.

In the illustrated embodiment, the first source IP circuit block 101 and the second source IP circuit block 102 each send data that is merged by the destination IP circuit block 113.

For example, as shown in FIG. 4, first data from the first source IP circuit block 101 is provided to the output tightly coupled memory (TCM) 115 of the first dataflow gasket 111. The output TCM 115 converts the data to packets (for example, packet 121 with stream ID 123), which are sent by the first dataflow gasket 111 to the third dataflow gasket 113 over the gasket interconnect 104. Additionally, second data from the second source IP circuit block 102 is provided to the output TCM 116 of the second dataflow gasket 112. The output TCM 116 converts the data to packets (for example, packet 122 with stream ID 124), which are sent by the second dataflow gasket 112 to the third dataflow gasket 113 over the gasket interconnect 104.

The third dataflow gasket 113 receives the packets 121/122, which can be identified by the third dataflow gasket 113 as being directed to the third dataflow gasket 113 by way of the stream IDs 123/124. The third dataflow gasket 113 merges the first data and the second data into merged data that is stored in an input TCM 117 of the third dataflow gasket 113. Pointers from the output stream registers 118 are used to direct storage of the received data packets 121/122 into a circular buffer 119 of the input TCM 117.

The merged data is readable by the destination IP circuit block 103. Additionally, the data is readable without the destination IP circuit block 103 needing to have an understanding of how the data was merged and/or is stored within the dataflow gasket 113 to which it is coupled.

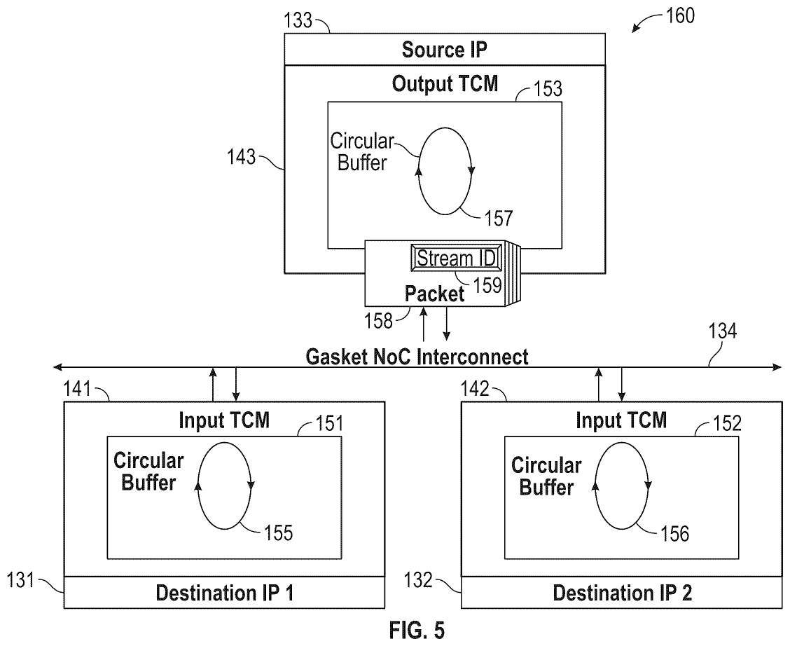

FIG. 5 is a schematic diagram of one embodiment of data stream forking using dataflow gaskets. As shown in FIG. 5, a first destination IP circuit block 131 is connected to a first dataflow gasket 141, a second destination IP circuit block 132 is connected to a second dataflow gasket 142, and a source IP circuit block 133 is connected to a third dataflow gasket 143. Additionally, the first dataflow gasket 141, the second dataflow gasket 142, and the third dataflow gasket 143 are connected to one another by gasket interconnect or NoC 134.

In the illustrated embodiment, the source IP circuit block 133 outputs a data stream that is forked into a first data stream received by the first destination IP circuit block 131 and a second data stream received by the second destination IP circuit block 132. In certain implementations, the first data stream and the second data stream carry identical data content but have different headers.

As shown in FIG. 5, a data stream from the source IP circuit block 133 is provided to the output TCM 153 of the third dataflow gasket 143. The output TCM 153 includes a circular buffer 157 that cases complexities in addressing with respect to the source IP circuit block 133 writing data to the output TCM 153. The output TCM 153 converts the data to packets (for example, packet 158 with stream ID 159), which are sent by the third dataflow gasket 143 to the first dataflow gasket 141 and/or the second dataflow gasket 142 over the gasket interconnect 104. By controlling the stream ID 159, all or a portion of the data stream can be directed to the first dataflow gasket 141 and/or the second dataflow gasket 142 (and thus to the first destination IP circuit block 131 and/or the second destination IP circuit block 132) as appropriate.

As shown in FIG. 5, the first dataflow gasket 141 includes an input TCM 151 for storing all or a portion of the data stream from data packets that are directed to the first dataflow gasket 141. The input TCM 151 includes a circular buffer 155, which allows the first destination IP circuit block 131 to access that data without needing to understand how the data was received and/or stored within the input TCM 151. Likewise, the second dataflow gasket 142 includes an input TCM 152 for storing all or a portion of the data stream from data packets that are directed to the second dataflow gasket 142. The input TCM 152 includes a circular buffer 156, which allows the second destination IP circuit block 132 to access stored data within the input TCM 152.

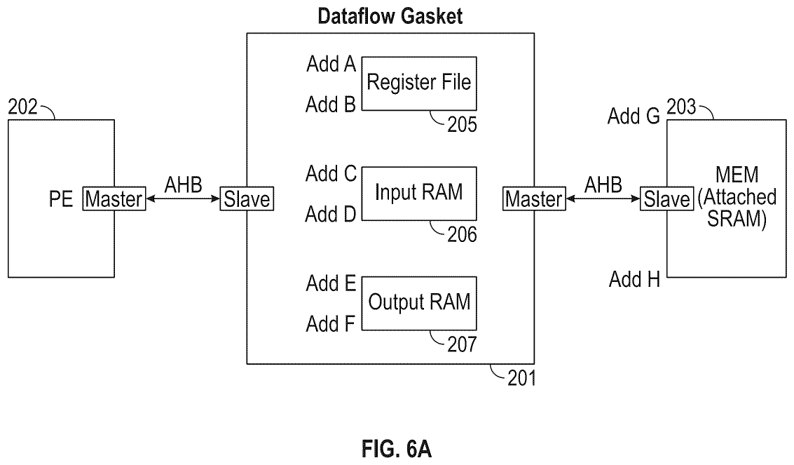

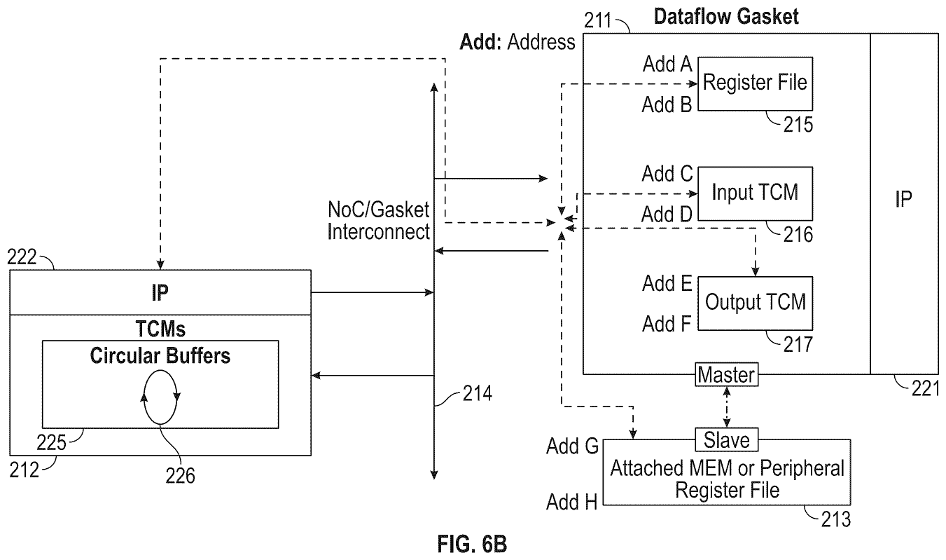

FIG. 6A is a schematic diagram of one embodiment of memory addressing for a dataflow gasket 201. In the illustrated embodiment, the dataflow gasket 201 includes a memory circuit that is tightly coupled to a processing engine or element (PE) 202 by way of an AHB interface. Additionally, the memory circuit of the dataflow gasket 201 is also supplemented by an attached memory (MEM) 203, such as a static random access memory (SRAM). The dataflow gasket 201 is coupled to the attached memory 203 by another AHB interface, in this embodiment. In certain implementations, all depicted components are formed on a common IC.

In the illustrated embodiment, the dataflow gasket 202 has its own address space that includes multiple regions. The multiple regions include a register file 205 (with addresses ranging from Add A to Add B), an input random access memory (RAM) 206 (with addresses ranging from Add C to Add D) implementing circular buffers for incoming data streams, an output RAM 207 (with addresses ranging from Add E to Add F) implementing circular buffers for outgoing data streams, and the attached memory 503 (with addresses ranging from Add G to Add H).

The address space of the dataflow gasket 201 need not be connected to the address space of the PE 202 in any manner. Rather, the PE 202 can read or write data to the dataflow gasket 201 directly and/or by way of circular buffers (implemented using the input RAM 206 and the output RAM 207). Since dataflow gaskets also connect to each other using their own gasket interconnect/NoC/the dataflow gaskets do not interfere with any other subsystem and provide a mechanism to connect different subsystems without being part of any PE's address space. Rather, the data transfer is stream based and data is read and/or written by PEs using circular buffers.

FIG. 6B is a schematic diagram of another embodiment of memory addressing for a dataflow gasket.

In the illustrated embodiment, a first dataflow gasket 211 includes a memory circuit that is tightly coupled to a first IP circuit block 221 as well as to an attached memory 213, which can correspond to an attached RAM or peripheral register file. The first dataflow gasket 211 has its own address space that includes multiple regions including a register file 215, input TCM 216 with circular buffers for handling incoming data streams, an output TCM 217 with circular buffers for handling outgoing data streams, and the attached memory 213.

As shown in FIG. 6B, the first dataflow gasket 211 is connected to a second dataflow gasket 212 by way of gasket interconnect/NoC 214. The second dataflow gasket 212 includes TCMs 225 that are tightly coupled to a second IP circuit block 222. The TCMs 225 include one or more circular buffers 226 for handling incoming and outgoing data streams.

With continuing reference to FIG. 6B, the second dataflow gasket 212 has been setup to read, write, and/or otherwise monitor the data stored in the address space of the first dataflow gasket 211. Accordingly, when the address space of the attached memory 213 is mapped to the local address space of the first dataflow gasket 211, the attached memory 213 can be setup and monitored by any IP circuit block (for instance, the IP circuit block 222) on the NoC 214.

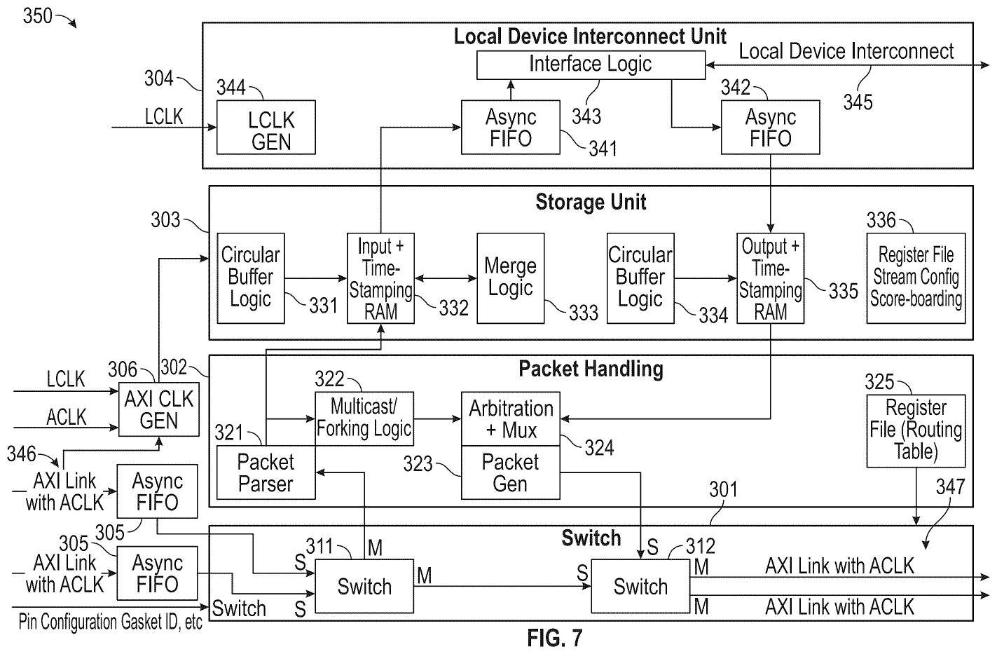

FIG. 7 is a schematic diagram of another embodiment of a dataflow gasket 350. The dataflow gasket 350 includes a crossbar switch 301, a packing handling circuit 302, a memory circuit 303 (also referred to as a storage unit), a local device interconnect circuit 304, asynchronous first-in first-out (FIFO) circuitry 305, and a clock generation circuit 306. The dataflow gasket 350 connects to an IP circuit block by way of local device interconnect 345, and connects to gasket interconnect/NoC by way of input ports 346 and output ports 347.

In the illustrated embodiment, the crossbar switch 301 includes an input-side switch 311 and an output-side switch 312. Additionally, the packet handling circuit 302 includes a packet parser 321, multicast/forking logic 322, a packet generation circuit 323, an arbitration and muxing circuit 324, and a register file 325 providing a routing table. Furthermore, the memory circuit 303 includes input circular buffer logic 331, input and time-stamping RAM 332, merge logic 333, output circular buffer logic 334, output and time-stamping RAM 335, and a register file 336 providing stream configuration and score boarding. Additionally, the local device interconnect unit 304 includes a local clock generation circuit 344, an input asynchronous FIFO 341, an output asynchronous FIFO 342, and interface logic 343.

With continuing reference to FIG. 7, the data path of the dataflow gasket 350 generally includes two major sub-blocks including a routing unit and a stream unit. The routing unit can be sub-divided into the packing handling circuit 302 and the crossbar switch 301. Additionally, the stream unit can be subdivided into the storage unit 303 and the local device interconnect unit 304.

The crossbar switch 301 connects to the crossbar switches of other dataflow gaskets by way of gasket interconnect/NoC. In the illustrated embodiment, the dataflow gasket 350 communicates with other dataflow gaskets by way of a multi-cycle bus, which can have unfixed latency in some implementations.

In one example, the multi-cycle bus can correspond to an N-cycle bus that can perform component transactions (read address, write address, read data, write data, and write acknowledge) with arbitrary pipelining. An N-cycle bus allows one transfer per cycle, but operates with latency that is not fixed. For instance, an Advanced Extensible Interface (AXI) can operate in this manner.

In another example, a two cycle un-pipelined bus performs a read operation by broadcasting a read transaction request on a first cycle and returning data on a second cycle, in which the second cycle does not contain another transaction request. For instance, an Advanced Peripheral Bus (APB) can operate in this manner. Although various examples of bus architectures for gasket interconnect are provided, other implementations are possible.

As shown in FIG. 7, the dataflow gasket 350 includes various register files. Such register files can be used to store routing unit information such as gasket ID and routing table. Additionally, the register files can include output stream configuration registers for running a desired number of output streams, and input stream configuration registers for running a desired number of input streams. Furthermore, the register files can include configuration registers used for enabling or disabling gasket features, such as those related to buffer allocation.

The input-side switch 311 serves to route incoming data through to the output-side switch 312 and/or to the storage unit 303 (by way of the packet parser 321). The input-side switch 311 can provide a stream ID to the packet parser 321, which can determine whether or not a particular received data packet is intended for the dataflow gasket 350. The output-side switch 312 can provide data coming through from the input-side switch 311 or data from the packet generation circuit 323 to the output ports 347.

With continuing reference to FIG. 7, the multicast/forking logic 322 can work in combination with the arbitration/multiplexing circuit 324 to facilitate broadcast of a packet to multiple dataflow gaskets. For example, a source dataflow gasket can send a list of all receiving dataflow gaskets as part of a packet. Once received at a given dataflow gasket, the dataflow gasket can send a list of all recipients of the stream as part of the packet and remove its own ID from the header.

The input and timing stamping RAM 332 serves to store incoming data. In this example, timestamp access for a FIFO mode is provided. Such a FIFO mode can increment a write pointer for writes and a read pointer for reads. The pointers correspond to addresses to the RAMs and point to a particular location inside the circular buffer of a stream. Thus, working in combination with the circular buffer logic 331, the input and timing stamping RAM 332 implements a circular buffer.

In the illustrated embodiment, merge logic 333 is included to facilitate a merge of data streams from multiple sources. For example, the merge logic 333 can facilitate the merge operation discussed earlier with respect to FIG. 4.

The output and timing stamping RAM 335 serves to store outgoing data. Working in combination with the circular buffer logic 334, the output and timing stamping RAM 335 implements a circular buffer.

The storage unit 303 can operate with a first clock signal from the AXI clock generation circuit 306, while the local device interconnect unit 304 can operate with a second clock signal from the local clock generation circuit 344. The first and second clock signals can be asynchronous.

Accordingly, the input asynchronous FIFO 341 and the output asynchronous FIFO 342 are included and controlled by the interface logic 343. The asynchronous FIFOs 341/342 aid in communicating data between the storage unit 303 and an IP circuit block coupled to the dataflow gasket 350 by way of the local device interconnect 345.

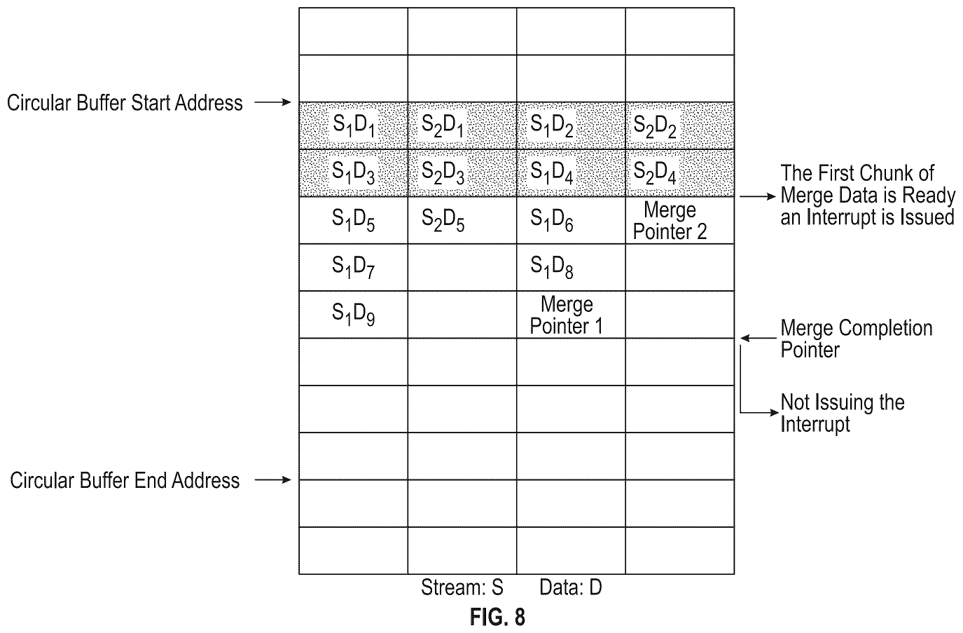

FIG. 8 is a schematic diagram of one embodiment of an address space for merging data using a circular buffer of a dataflow gasket. For example, as described earlier with respect to FIG. 4, multiple streams can be merged at a destination.

In certain implementations, each source stream is programmed with the number of streams to be joined and the resulting stream ID. By implementing the source streams in this manner, the destination knows how many streams to join and a space requirement irrespective of which source stream starts first.

With reference to FIG. 8, a circular buffer start address and a circular buffer end address are depicted. Each address can be stored in a register. The circular buffer size corresponds to a difference between the buffer end address and the buffer start address.

At the start of a stream, a merge pointer for each participating stream is set to merge base address plus merge byte offset. Additionally, every new datum belonging to this stream is written at the merge pointer and the merge pointer is incremented by size of the incoming data.

Furthermore, at the start of the stream, a merge completion pointer for each participating stream is set to merge base address plus merge byte offset plus interrupt size. When the merge pointer becomes equal to the merge completion pointer, all the data for a stream has arrived. Accordingly, this increments the merge counter and increments the merge completion counter by the interrupt size, which will be the next merge completion pointer value.

When merge counters of all constituent streams become greater than the interrupt counter, the interrupt counter in each stream configuration register set is incremented while the merge counter is decremented.

In certain implementations, when initially establishing a stream, a destination node can send an error response to all source nodes if it does not have enough resources available for a merge. Thus, source nodes can wait for an okay response on start of the header transaction before sending the rest of the stream.

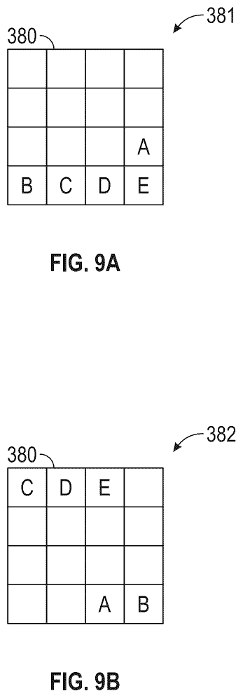

FIG. 9A is a schematic diagram of one example of memory allocation 381 in a circular buffer. FIG. 9B is a schematic diagram of another example of memory allocation 382 in a circular buffer.

In the example of FIG. 9A, a memory circuit or memory 380 stores data blocks A, B, C, D, and E in the final five memory blocks. In the example of FIG. 9B, the memory 380 also stores the same data blocks A, B, C, D, and E. However, in comparison to the example of FIG. 9A in which the data blocks are stored in the final five memory blocks of the memory 380, in the example of FIG. 9B the data blocks are stored in the first three memory blocks and the final two memory blocks of the memory 380.

By using a circular buffer, the data blocks A, B, C, D, and E can be read from the memory 380 without needing to know the precise addresses in which the data blocks A, B, C, D, and E are stored.

Rather, an IP circuit block can read or write to a memory of a dataflow gasket without needing to understand or know the details of how the dataflow gasket stores the data.

### CONCLUSION

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments.

1. An integrated circuit (IC) comprising:
a first circuit block; and
a first dataflow gasket coupled to the first circuit block, wherein the first dataflow gasket comprises:
a crossbar switch electrically connected to interconnect of a network of dataflow gaskets; and
a memory circuit electrically connected to the crossbar switch and accessible to the first circuit block and the first dataflow gasket, wherein the memory circuit includes at least one circular buffer.

2. The IC of claim 1, wherein the memory circuit includes an input memory configured to receive data from the crossbar switch and an output memory configured to provide data to the crossbar switch, wherein the input memory is readable by the first circuit block and the output memory is writable by the first circuit block.

3. The IC of claim 2, wherein the at least one circular buffer includes a first circular buffer of the input memory and a second circular buffer of the output memory.

4. The IC of claim 2, wherein the input memory is configured to activate an interrupt signal in response to receiving data from the crossbar switch.

5. The IC of claim 2, wherein the first dataflow gasket further comprises a packet handling circuit configured to process the data received from the crossbar switch as a plurality of data packets.

6. The IC of claim 5, wherein the first dataflow gasket further comprises a register file storing a gasket identifier, wherein the packet handling circuit is configured to determine when a data packet of the plurality of data packets is directed to the first dataflow gasket based on comparing a stream identifier of the data packet to the gasket identifier.

7. The IC of claim 1, wherein an address space of the memory circuit is separate from an address space of the first circuit block.

8. The IC of claim 7, further comprising a peripheral memory attached to the first dataflow gasket and included in the address space of the memory circuit.

9. The IC of claim 7, further comprising a second dataflow gasket connected to the first dataflow gasket over the interconnect, wherein the second dataflow gasket is configured to read and write data in the address space of the memory circuit of the first dataflow gasket.

10. The IC of claim 1, wherein the first circuit block comprises a digital signal processor, a central processing unit, a neural processing unit, a reconfigurable compute unit, a digital-to-analog converter (DAC), or an analog-to-digital converter (ADC).

11. The IC of claim 1, further comprising a second dataflow gasket connected to the first dataflow gasket over the interconnect, a third dataflow gasket connected to the first dataflow gasket over the interconnect, a second circuit block coupled to the second dataflow gasket, and a third circuit block coupled to the third dataflow gasket.

12. The IC of claim 11, wherein the at least one circular buffer is configured to merge a first data stream sent by the second circuit block over the interconnect and a second data stream sent by the third circuit block over the interconnect.

13. The IC of claim 11, wherein the at least one circular buffer is configured to fork an outgoing data stream from the memory circuit into a first data stream sent to the second circuit block over the interconnect and a second data stream sent to the third circuit block over the interconnect.

14. A method of dataflow in an integrated circuit (IC), the method comprising:
receiving first data from interconnect of a network of dataflow gaskets as an input to a crossbar switch of a first dataflow gasket;
writing the first data to a memory circuit of the first dataflow gasket, the memory circuit coupled to the crossbar switch; and
providing the first data from the memory circuit to a first circuit block that is coupled to the first dataflow gasket, wherein providing the first data to the first circuit block includes using a first circular buffer to read the first data from the memory circuit.

15. The method of claim 14, further comprising writing second data from the first circuit block to the memory circuit using a second circular buffer.

16. The method of claim 14, wherein an address space of the memory circuit is separate from an address space of the first circuit block and a second dataflow gasket is connected to the first dataflow gasket over the interconnect, the method further comprising reading and writing data in the address space of the memory circuit of the first dataflow gasket using the second dataflow gasket.

17. The method of claim 14, further comprising a second dataflow gasket connected to the first dataflow gasket over the interconnect, a third dataflow gasket connected to the first dataflow gasket over the interconnect, a second circuit block coupled to the second dataflow gasket, and a third circuit block coupled to the third dataflow gasket.

18. The method of claim 17, further comprising using the first circular buffer to merge a first data stream sent by the second circuit block over the interconnect and a second data stream sent by the third circuit block over the interconnect.

19. The method of claim 17, further comprising using a second circular buffer of the memory circuit to fork an outgoing data stream from the memory circuit into a first data stream sent to the second circuit block over the interconnect and a second data stream sent to the third circuit block over the interconnect.

20. A dataflow gasket comprising:
local device interconnect for coupling to a circuit block;
a crossbar switch electrically connected to interconnect of a network of dataflow gaskets; and
a memory circuit electrically connected to the crossbar switch and accessible to the first circuit block and the first dataflow gasket, wherein the memory circuit includes at least one circular buffer.
